(19) United States
(12) Patent Application Publication
(10) Pub. No.: US 2025/0393278 A1
(43) Pub. Date: Dec. 25, 2025

(54) SEMICONDUCTOR DEVICE

(71) Applicant: ROHM CO., LTD., Kyoto (JP)

(72) Inventor: Shusaku FUJIE, Kyoto (JP)

(73) Assignee: ROHM CO., LTD., Kyoto (JP)

(21) Appl. No.: 19/239,147

(22) Filed: Jun. 16, 2025

(30) Foreign Application Priority Data
Jun. 25, 2024 (JP) 2024-101801

(51) Int. Cl. H10D 64/00; H03K 17/687; H10D 30/65; H10D 62/10; H10D 64/27

(52) U.S. Cl. CPC H10D 64/112; H03K 17/687; H10D 30/655; H10D 62/102; H10D 62/126; H10D 64/518; H10D 64/519

(57) ABSTRACT

A semiconductor device, including: a semiconductor substrate; the semiconductor layer including a first potential region having a drain region extending in a first direction, a second potential region having a source region surrounding the first potential region, and a drift region between the drain region and the second potential region; a field insulation film covering the drift region; and a field resistive film provided on the field insulation film and electrically connected to the first and second potential regions. The first potential region includes a linear region, and an end region that is continuously connected to the linear region and has a curved outer edge. A distance in the first direction between an end of the drain region and the end of the first potential region is shorter than a distance in a second direction between the drain region and an outer edge of the linear region.

### CROSS REFERENCE TO RELATED APPLICATION

This application is based upon and claims the benefit of priority of the prior Japanese Patent Application No. 2024-101801, filed on Jun. 25, 2024, the entire contents of which are incorporated herein by reference.

### TECHNICAL FIELD

The present disclosure relates to a semiconductor device.

### BACKGROUND

Patent Document 1 discloses a semiconductor device that includes a high potential region, a low potential region, and a drift region. The drift region is formed in the area between the high potential region and the low potential region. The semiconductor device described in Patent Document 1 further has a field insulation film that covers the drift region and a field resistive film, which is provided on top of the field insulation film and is electrically connected to both the high potential region and the low potential region.

### RELATED ART DOCUMENTS

[Patent Document 1] Japanese Unexamined Patent Application Publication No. 2001-129053

### BRIEF DESCRIPTION OF THE DRAWINGS

FIG. 1 is a plan view illustrating a chip of a semiconductor device according to one embodiment.

FIG. 2 is an enlarged view of region II shown in FIG. 1.

FIG. 3 is a schematic diagram for describing a first potential region and a second potential region of the transistor region shown in FIG. 2.

FIG. 4 is an enlarged partial cross-sectional view of the transistor region at the position of dash-dot line IV shown in FIG. 3.

FIG. 5 is an enlarged partial cross-sectional view of the transistor region at the position of dash-dot line V shown in FIG. 3.

FIG. 6 is an enlarged partial cross-sectional view of the transistor region at the position of dash-dot line VI shown in FIG. 3.

FIG. 7 is a diagram for describing an end region included in the first potential region.

FIG. 8 is a schematic diagram illustrating the first potential region according to Modification Example 1.

FIG. 9 is a schematic diagram illustrating the first potential region according to Modification Example 2.

### DESCRIPTION OF EMBODIMENTS

Embodiments of the present disclosure will be described in detail below with reference to the accompanying drawings. In the following description, elements having the same or equivalent functions are denoted by the same reference numerals, and redundant descriptions will be omitted. The term “same” and similar expressions used in this specification are not limited to meanings of “absolute identical.” The drawings are intended to conceptually illustrate the embodiments, and the dimensions and relative ratios of the depicted components may differ from actual ones.

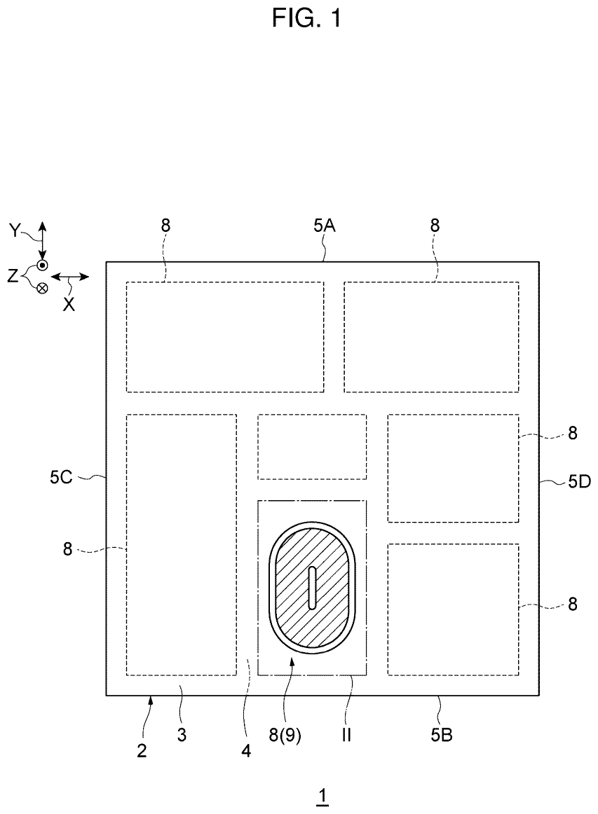

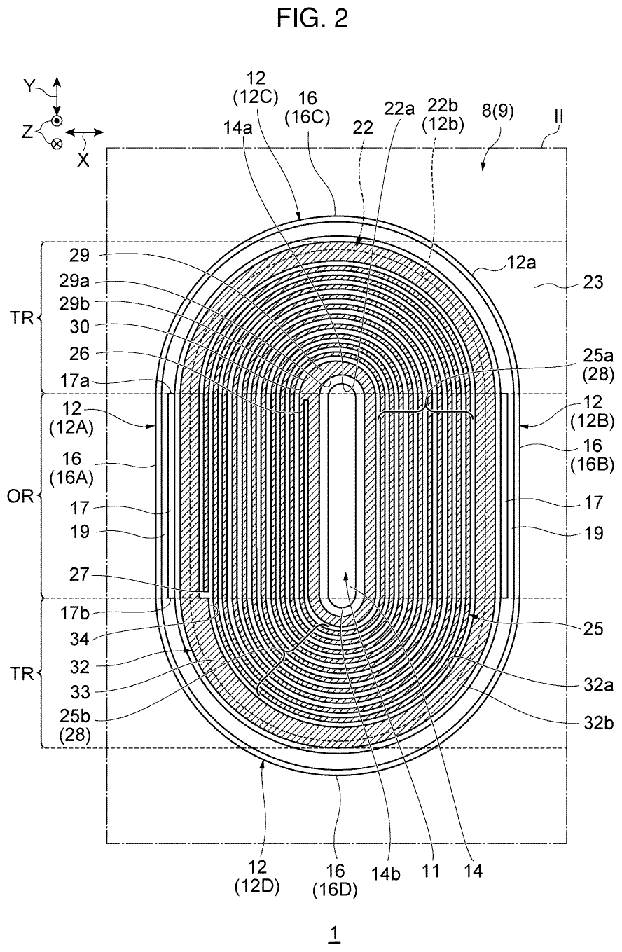

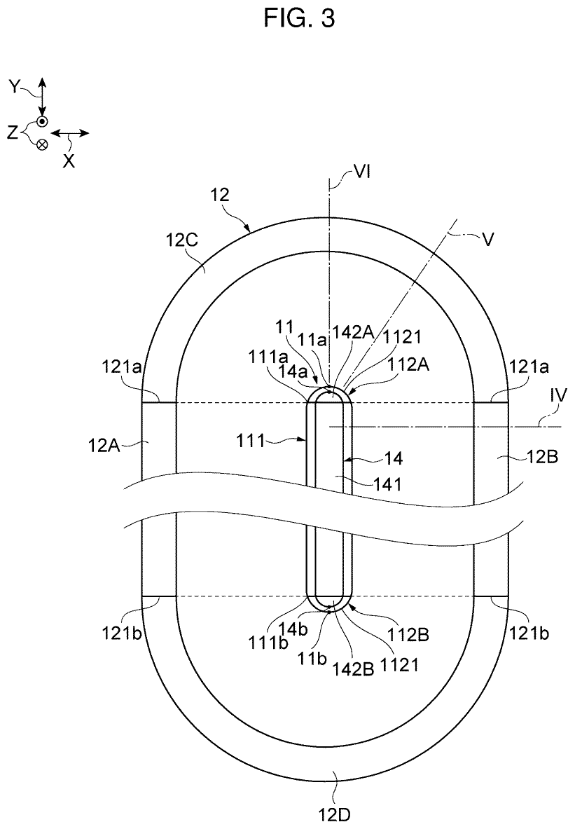

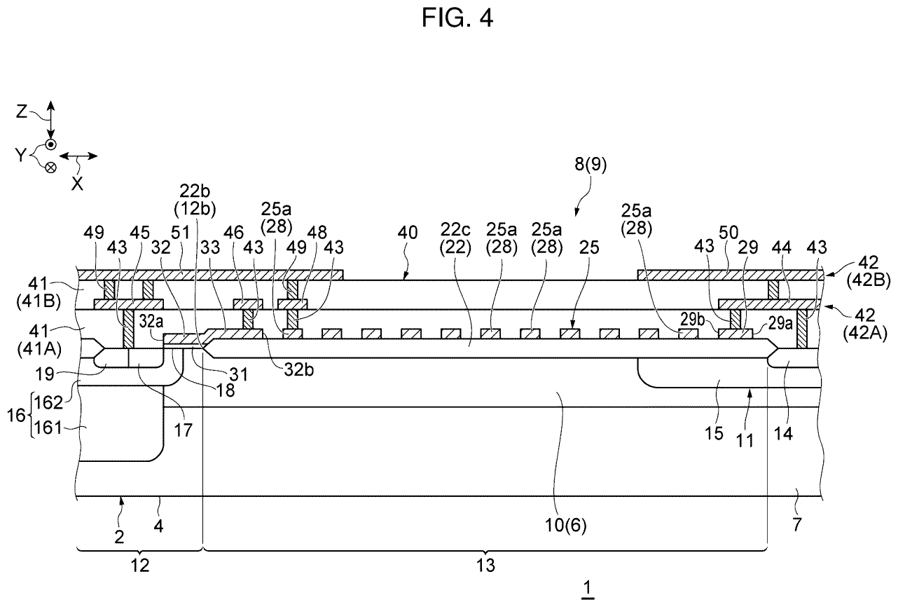

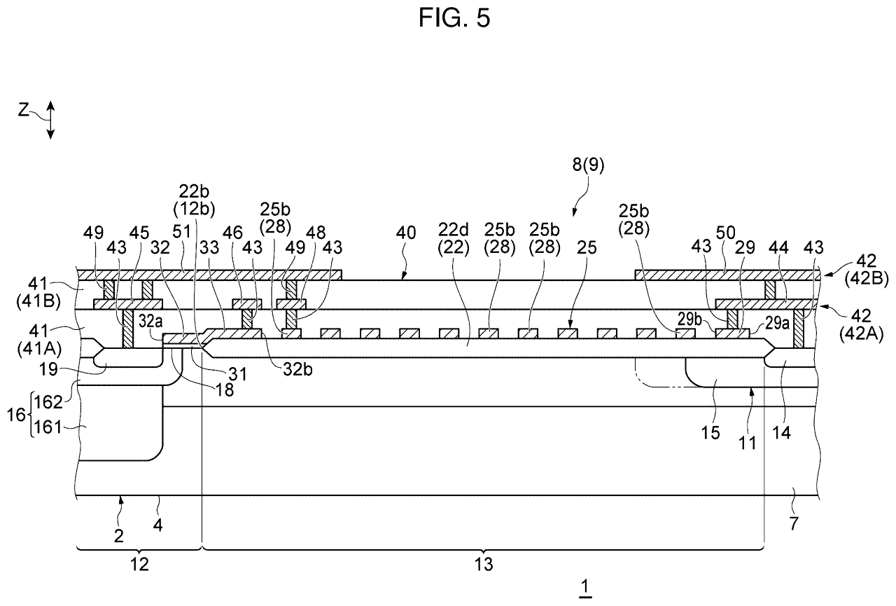

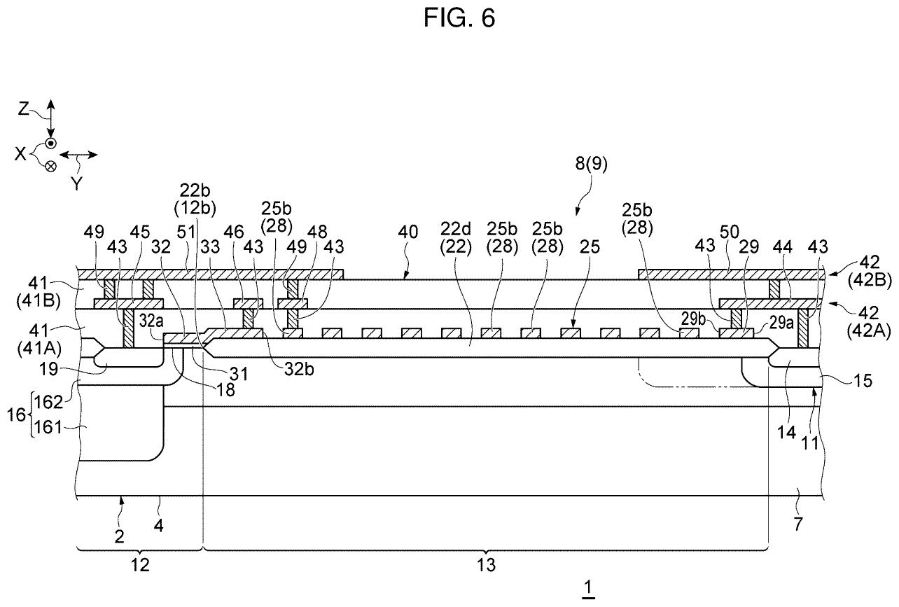

FIG. 1 is a plan view illustrating a chip of a semiconductor device according to the present embodiment. FIG. 2 is an enlarged view of region II shown in FIG. 1. FIG. 3 is a schematic diagram for describing a first potential region and a second potential region included in the transistor region shown in FIG. 2. FIG. 4 is a partially enlarged cross-sectional view of the transistor region at the position of the dash-dot line IV shown in FIG. 3. FIG. 4 illustrates an example of the cross-sectional structure of an operational region (OR) (see FIG. 2), which will be described later. FIG. 5 is a partially enlarged cross-sectional view of the transistor region at the position of the dash-dot line V shown in FIG. 3. FIG. 6 is a partially enlarged cross-sectional view of the transistor region at the position of the dashed line VI shown in FIG. 3. FIGS. 5 and 6 illustrate examples of the cross-sectional structure of a terminal region (TR) (see FIG. 2), which will also be described later.

As shown in FIG. 1, the semiconductor device 1 includes a silicon chip 2 (semiconductor chip) having a rectangular cuboid shape. The chip 2 is one of a plurality of devices formed, for example, on a silicon wafer with a diameter of 300 mm (approximately 12 inches).

The chip 2 includes a first main surface 3 and a second main surface 4, which are a pair of main surfaces, and includes a first side surface 5A, a second side surface 5B, a third side surface 5C, and a fourth side surface 5D, which connect the first main surface 3 and the second main surface 4. In the following description, the extending direction of the first side surface 5A and the second side surface 5B in a plan view is referred to as the X direction (second direction), and the extending direction of the third side surface 5C and the fourth side surface 5D in a plan view is referred to as the Y direction (first direction). The normal direction to the first main surface 3 and the second main surface 4 is referred to as the Z direction. The Y direction is a direction that intersects the X direction in a plan view, and the Z direction corresponds to the thickness direction of the chip 2.

The first main surface 3 and the second main surface 4 are formed in a rectangular shape when viewed from the Z direction; however, this is not limiting. In this embodiment, the first main surface 3 serves as the top surface, and the second main surface 4 serves as the bottom surface. Accordingly, a structure located near the first main surface 3 in the Z direction corresponds to a structure located on the top side (upper side) of the semiconductor device 1, whereas a structure located near the second main surface 4 in the Z direction corresponds to a structure located on the bottom side (lower side) of the semiconductor device 1.

The semiconductor device 1 includes a semiconductor region 6 (see FIGS. 4 to 6) located in an upper region within the chip 2. The semiconductor region 6 is a region having a first conductivity type and has a layer shape extending along the first main surface 3. Therefore, the semiconductor region 6 may also be referred to as a semiconductor layer. The semiconductor region 6 constitutes at least a part of an epitaxial semiconductor layer. The semiconductor region 6 is exposed at the first main surface 3, the first side surface 5A, the second side surface 5B, the third side surface 5C, and the fourth side surface 5D. The thickness of the semiconductor region 6 is, for example, not less than 5 μm and not more than 20 μm. In this embodiment, the first conductivity type is n-type. The n-type impurity concentration of the semiconductor region 6 is, for example, between 1.0×10¹³ cm⁻³ and 1.0×10¹⁵ cm⁻³.

A semiconductor device 1 includes a semiconductor region 7 located in the lower region within the chip 2. The semiconductor region 7 is characterized by having a second conductivity type and being fixed at a predetermined potential, presenting a layer shape extending along the second main surface 4. The semiconductor region 7 is exposed from the second main surface 4 as well as from the first side surface 5A, the second side surface 5B, the third side surface 5C, and the fourth side surface 5D. In this embodiment, the semiconductor region 7 is fixed at a back-gate potential. The back-gate potential may be a reference potential serving as the basis for circuit operation, or it may be a ground potential. In this embodiment, the second conductivity type is p-type. The p-type impurity concentration of the semiconductor region 7 is, for instance, between 1.0×10¹² cm⁻³ and 1.0×10¹⁴ cm⁻³.

Semiconductor region 7 is connected to the semiconductor region 6. The thickness of the semiconductor region 7 may be between 50 μm and 400 μm. The semiconductor region 7 constitutes at least a part of a p-type semiconductor substrate. In other words, the chip 2 includes the semiconductor region 6 contained in an epitaxial semiconductor layer, as well as the semiconductor region 7 contained in the semiconductor substrate. In other words, the chip 2 has a laminated structure that includes both the semiconductor substrate and the epitaxial semiconductor layer positioned on the semiconductor substrate.

A semiconductor device 1 includes a plurality of device regions 8 delineated on the first main surface 3. In the semiconductor device 1, the number and arrangement of the plurality of device regions 8 are determined as appropriate. Each of the plurality of device regions 8 includes functional devices formed utilizing regions both inside and outside of the chip 2. The functional devices include at least one of, for example, a semiconductor switching device, a semiconductor rectifying device, and a passive device. The functional devices may also include a network in which at least two of a semiconductor switching device, a semiconductor rectifying device, and a passive device are combined.

A semiconductor switching device may include at least one of the following: a MISFET (Metal Insulator Semiconductor Field Effect Transistor), a BJT (Bipolar Junction Transistor), an IGBT (Insulated Gate Bipolar Junction Transistor), and a JFET. The semiconductor rectifying device may include at least one of the following: a pn junction diode, a pin junction diode, a Zener diode, a Schottky barrier diode, and a fast recovery diode. The passive device may include at least one of the following: a resistor, a capacitor, an inductor, and a fuse.

A plurality of device regions 8 each includes at least one transistor region 9. The transistor region 9 includes an FET structure (transistor structure). In this embodiment, the FET structure has a so-called LDMISFET (Lateral Double diffused MISFET) structure. The aforementioned FET structure is a high breakdown voltage device capable of withstanding a drain voltage of 800V or more when in the off state. The structure of the transistor region 9 will be described below with reference to FIGS. 2 to 6.

The transistor region 9 is an area defined by the isolation region and includes an n-type impurity region 10 located within the semiconductor region 6.

In this embodiment, the impurity region 10 is a part of the section segmented by the isolation region within the semiconductor region 6. The n-type impurity concentration of the impurity region 10 is, for example, equal to the n-type impurity concentration of the semiconductor region 6. Although the impurity region 10 exhibits an elongated elliptical shape in a plan view, it is not limited to this. The impurity region 10 may also assume a circular shape, an elliptical shape, or a polygonal shape (such as a quadrilateral shape).

The transistor region 9 includes a first potential region 11, a second potential region 12, and a drift region 13. The first potential region 11 is an area where a first potential is applied. The second potential region 12 is an area where a second potential is applied. For instance, the first potential region 11 is a high potential region where a high potential (first potential) is applied, and the second potential region 12 is a low potential region where a low potential (second potential) less than the high potential is applied. The drift region 13 is the area between a drain region 14, which is included in the first potential region 11, and the second potential region 12. Hereinafter, unless otherwise specified, the first potential region 11 will be referred to as the high potential region, and the second potential region 12 will be referred to as the low potential region.

The first potential region 11 is located at the central part of the impurity region 10 in a plan view. The first potential region 11 has an elongated elliptical shape with the Y direction as the major axis and the X direction as the minor axis. Specifically, as shown in FIG. 3, the first potential region 11 includes a linear region (first linear region) 111 and two end regions 112A and 112B. In FIG. 3, for the sake of convenience in description, the boundaries between the linear region 111 and the end region 112A, as well as the boundary between the linear region 111 and the end region 112B, are indicated with solid lines.

The linear region 111 is a band-shaped area extending in the Y direction.

The end region 112A is an area that includes an end (second end) 11a in the Y direction of the first potential region 11. The end region 112B is an area that includes an end (second end) 11b in the Y direction of the first potential region 11. The end 11b is the end opposite to the end 11a in the Y direction.

The end region 112A is continuously connected to an end (first end) 111a of the linear region 111 in the Y direction, and the end region 112B is continuously connected to an end (first end) 111b of the linear region 111 in the Y direction. The end 111b is the end located opposite to the end 111a in the Y direction.

The outer edges (first outer edges) 1121 of each end region 112A and 112B exhibit a curved shape. In a plan view, the shape of the outer edge 1121 is, for example, an arc. The end region 112A is an area defined by the end 111a and the outer edge 1121. The end region 112B is an area defined by the end 111b and the outer edge 1121.

The first potential region 11 includes a drain region 14 and a well region 15 (see FIGS. 4 to 6). Each of the drain region 14 and the well region (first semiconductor region) 15 is provided above the semiconductor region 6.

The drain region 14 constitutes a part of the first main surface 3. In a plan view, the drain region 14 extends in the Y direction. At least a portion of the drain region 14 is included in the linear region 111.

In this embodiment, the drain region 14 extends in the Y direction in a plan view and exhibits an elongated elliptical shape with both rounded ends. Specifically, as shown in FIG. 3, the drain region 14 includes a strip-shaped linear region 141 extending in the Y direction, and two end regions 142A and 142B.

The linear region 141 of the drain region 14 is contained within the linear region 111 of the first potential region 11 in a plan view. The length in the Y direction of the linear region 141 is the same as that of the linear region 111. The end region 142A of the drain region 14 is continuously connected to one end of the linear region 141 and is included in the end region 112A of the first potential region 11. The end (third end) 14a of the drain region 14 is located in the end region 142A. The end region 142B of the drain region 14 is continuously connected to the other end of the linear region 141 and is included in the end region 112B of the first potential region 11. The end (third end) 14b of the drain region 14 is located in the end region 142B. The linear region 141 of the drain region 14 is the portion that substantially functions as the drain in the transistor.

In a plan view, the well region 15 surrounds the drain region 14. In a plan view, the drain region 14 is spaced apart from the periphery of the well region 15. That is, the drain region 14 is located inward from the periphery of the well region 15. In a plan view, the outer edge of the well region 15 defines the outer edge of the first potential region 11. Well region 15 is in contact with the drain region 14. As a result, the potential of the well region 15 is fixed to be equal to the potential of the drain region 14 (drain potential).

The n-type impurity concentration of the drain region 14 is higher than that of the well region 15. The n-type impurity concentration of the drain region 14 is, for example, between 1.0×10¹⁸ cm⁻³ and 1.0×10²¹ cm⁻³. The n-type impurity concentration of the well region 15 is higher than that of the impurity region 10. The n-type impurity concentration of the well region 15 is, for example, between 1.0×10¹⁵ cm⁻³ and 1.0×10¹⁸ cm⁻³.

The second potential region 12, in a plan view, is positioned within the aforementioned isolation region and surrounds the first potential region 11. The second potential region 12 exhibits an elongated annular elliptical shape where the Y direction is the major axis and the X direction is the minor axis. As shown in FIGS. 2 and 3, the second potential region 12 has two linear regions (second linear regions) 12A and 12B, as well as two curved regions 12C and 12D.

The linear regions 12A and 12B are positioned oppositely to each other across the first potential region 11 in the X direction. The linear regions 12A and 12B are linear sections (or strip-like sections) that extend along the Y direction in a plan view and extend parallel to each other.

The lengths of the linear regions 12A and 12B in the Y direction are the same as the length of the linear region 111 of the first potential region 11. The positions of the linear regions 12A and 12B in the Y direction are the same as the position of the linear region 111. As indicated by the dashed lines in FIG. 3, the Y direction position of one end 121a of each linear region 12A and 12B is the same as the position of the end 111a of the linear region 111, and the Y direction position of the other end 121b of each linear region 12A and 12B is the same as the position of the end 111b of the linear region 111. The dashed lines in FIG. 3 are intended to illustrate the positional relationship of the linear regions 12A and 12B relative to the linear region 111. In this embodiment, the length and arrangement of the linear regions 12A and 12B in relation to the linear region 111 are not limited to the illustrated form.

The curved region (first curved region) 12C connects one end 121a of the linear region 12A with one end 121a of the linear region 12B. The curved region 12C extends in an arc-shaped band between one end 121a of the linear region 12A and one end 121a of the linear region 12B. The radius of curvature of both the outer edge 12a and inner edge 12b of the second potential region 12 may be the same in the curved region 12C.

The curved region (second curved region) 12D connects the other end 121b of the linear region 12A with the other end of the linear region 12B. The curved region 12D extends in an arc-shaped band between the other end 121b of the linear region 12A and the other end of the linear region 12B. The radius of curvature of both the outer edge 12a and inner edge 12b of the second potential region 12 may be the same in the curved region 12D. The radius of curvature of both the outer edge 12a and inner edge 12b of the second potential region 12 in the curved region 12D may be the same as the radius of curvature in the curved region 12C.

The second potential region 12 includes a p-type body region 16 (see FIGS. 4-6) located between the aforementioned isolation region and the well region 15. The body region 16 extends, for example, along the periphery of the impurity region 10. Specifically, the body region (second semiconductor region) 16 exhibits an elongated annular elliptical shape enclosing the impurity region 10. The outer edge of the body region 16 defines the outer edge 12a of the second potential region 12.

As shown in FIGS. 4 to 6, the body region 16 extends in the Z direction from the first main surface 3 to the boundary of the semiconductor region 6 and the semiconductor region 7. In this embodiment, the body region 16 includes a first body region 161 and a second body region 162.

The first body region 161 is formed at the boundary between the semiconductor region 7 and the impurity region 10. The first body region 161 is formed with spacing from both the first main surface 3 and the second main surface 4 in the Z direction. The first body region 161 is electrically connected to semiconductor region 7. The first body region 161 has a higher p-type impurity concentration than the semiconductor region 7. The p-type impurity concentration of the first body region 161 is, for example, between 2.0×10¹⁵ cm⁻³ and 2.0×10¹⁸ cm⁻³.

The second body region 162 is formed in the area between the first main surface 3 and the first body region 161. The second body region 162 is electrically connected to the first body region 161. As illustrated in FIGS. 4 to 6, the second body region 162 may protrude toward the drain region 14 beyond the first body region 161. The second body region 162 has a lower p-type impurity concentration than the first body region 161. The p-type impurity concentration of the second body region 162 is, for example, between 1.0×10¹⁵ cm⁻³ and 1.0×10¹⁸ cm⁻³.

As described above, the first body region 161 is electrically connected to the semiconductor region 7, and the second body region 162 is electrically connected to the first body region 161. Therefore, the first body region 161 and the second body region 162 are fixed to the potential of the semiconductor region 7 (for example, the back gate potential).

The body region 16 is illustrated in a configuration having a first body region 161 and a second body region 162. However, the body region 16 may also be a single unified region where the first body region 161 and the second body region 162 are integrated. In other words, the p-type impurity concentration of the first body region 161 and the second body region 162 may be the same. In this case, the p-type impurity concentration ranges, for example, between 1.0×10¹⁵ cm⁻³ and 1.0×10¹⁸ cm⁻³. In this configuration, the body region 16 is electrically connected to the semiconductor region 7, and the potential of the body region 16 is fixed to the potential of the semiconductor region 7 (for example, the back gate potential).

As shown in FIG. 2, the body region 16 is divided into a first region 16A, a second region 16B, a third region 16C, and a fourth region 16D. Each of the first region 16A and the second region 16B is a linear section (or strip-like section) that extends along the Y direction in a plan view and extends parallel to each other. The first region 16A is included in the linear region 12A. The second region 16B is included in the linear region 12B.

The third region 16C is a curved portion connecting one end of the first region 16A in the Y direction with one end of the second region 16B in the Y direction. In this embodiment, the third region 16C is included within the curved region 12C. The third region 16C extends in an arc-shaped band between the one end of the first region 16A and the one end of the second region 16B.

The fourth region 16D is a curved portion that connects the other end of the first region 16A in the Y direction with the other end of the second region 16B in the Y direction. In this embodiment, the fourth region 16D is included within the curved region 12D. The fourth region 16D extends in an arc-shaped band between the other end of the first region 16A and the other end of the second region 16B.

The semiconductor device 1 includes a source region 17 provided within the body region 16. In the present embodiment, the semiconductor device 1 includes a plurality of source regions 17; however, the configuration is not limited thereto. Each of the plurality of source regions 17 is an n-type region and is fixed to a source potential. Specifically, in each of the plurality of source regions 17, the source potential is applied from outside the chip 2. In the impurity region 10, a p-type channel region 18 of the FET structure is formed between the source region 17 and the drift region 13 in the X direction. Accordingly, a current path extending in the X direction is formed within the impurity region 10 between the source region 17 and the drift region 13, along the X direction. The source potential corresponds to the above-mentioned second potential.

The n-type impurity concentration of the source region 17 is higher than that of the well region 15. The n-type impurity concentration of the source region 17 may be equal to the n-type impurity concentration of the drain region 14. For example, the n-type impurity concentration of the source region 17 ranges between 1.0×10¹⁸ cm⁻³ and 1.0×10²¹ cm⁻³. In the channel region 18, the conduction and non-conduction of the current path between the drain region 14 and the source region 17 are controlled.

Each of the plurality of source regions 17 exhibits a strip-like shape in a plan view. Each of the plurality of source regions 17 is located within the body region 16 and positioned inwardly of the outer edge of the body region 16. Each of the plurality of source region 17 constitutes a part of the first main surface 3, specifically a portion of the surface layer of the body region 16. Some of the plurality of source regions 17 are located within the first region 16A. The respective ends of these source regions in the Y direction are positioned inward of the respective ends of the first region 16A in the Y direction; however, this configuration is not limiting. The remaining source regions of the plurality of source regions 17 are located within the second region 16B. The respective ends of these remaining source regions in the Y direction are positioned inward of the respective ends of the second region 16B in the Y direction; however, this configuration is not limiting. None of the plurality of source regions 17 are located within the third region 16C or the fourth region 16D. In the Y direction, the length of each source region 17 is, for example, equal to or less than the length of the drain region 14. For instance, when a single source region 17 is located in the body region 16, that source region 17 is located in at least one of the first region 16A or the second region 16B of the body region 16.

The second potential region 12 includes a contact region 19 provided within the body region 16. In this embodiment, the contact region 19 exhibits a strip-like shape in a plan view and is positioned within the body region 16, inward from the outer edge of the body region 16. The contact region 19 is formed in an elongated annular elliptical shape along the body region 16 in a plan view. The contact region 19 constitutes a part of the first main surface 3, specifically, a part of the surface layer of the body region 16.

The contact region is a p-type region. The p-type impurity concentration of the contact region 19 may be higher than the p-type impurity concentration of the body region 16. For example, the p-type impurity concentration of the contact region 19 may range between 1.0×10¹⁸ cm⁻³ and 1.0×10²¹ cm⁻³.

In the body region 16, where the source region 17 is present (for example, the first region 16A and the second region 16B), the contact region 19 is positioned between the source region 17 and the outer edge of the body region 16 in a plan view. The contact region 19 is located closer to the outer edge of the body region 16 than to the source region 17. The contact region 19 may be adjacent to the source region 17.

In this manner, in the portion of the contact region 19 that is adjacent to the source region 17, the width of the contact region 19 may be narrower than the width in other portions. The above-mentioned width of the contact region 19 is, in a plan view, the length in a direction orthogonal to the extending direction of the contact region 19. In portions of the contact region 19 that are not parallel to the source region 17, the width may be the same as the width of the body region 16.

Instead of a single contact region 19 having an elongated annular elliptical shape, the semiconductor device 1 may include a plurality of contact regions 19. In this case, the plurality of contact regions 19 include contact regions 19 arranged in the first region 16A and contact regions 19 arranged in the second region 16B.

The semiconductor device 1 includes an n-type drift region 13 located between the drain region 14 and the second potential region 12, positioned on the surface layer of the impurity region 10. The drift region 13, for example, exhibits an elongated annular elliptical shape surrounding the drain region 14 in a plan view.

In this embodiment, the drift region 13 includes a first section (linear section) extending in the Y direction parallel to both the first region 16A and the second region 16B, and a second section (arc section) extending in an arc shape parallel to both the third region 16C and the fourth region 16D. While the drift region 13 forms a current path in the portion along the first region 16A and the second region 16B, the drift region 13 does not form a current path in the portion along the third region 16C and the fourth region 16D.

The width of the drift region 13 corresponds to the distance between the drain region 14 and the second potential region 12. The width of the arc section of the drift region 13 may increase toward the center of the arc from the linear section. The width of the linear section of the drift region 13 may be substantially constant.

The semiconductor device 1 includes insulation films 22 and 23 that selectively cover the first main surface 3 in the transistor region 9. Each of the insulation films 22 and 23 contains silicon oxide. Each of the insulation films 22 and 23 includes a LOCOS film (Local Oxidation of Silicon film) formed by the selective oxidation of the first main surface 3, an embedded oxide film that fills shallow trenches provided on the first main surface 3 (STI: Shallow Trench Isolation), or the like. The insulation films 22 and 23 may have a single-layer structure or a laminated structure.

An insulation film (field insulation film) 22 is positioned over the semiconductor region 6 and covers the region between the drain region 14 and the second potential region 12 on the first main surface 3. The insulation film 22 is, for instance, located over the drift region 13 within the impurity region 10 and presents an elongated annular elliptical shape surrounding the drain region 14 in a plan view. The insulation film 22 includes an inner edge portion 22a and an outer edge portion 22b.

In FIG. 2, the outer edge portion 22b is indicated by dashed lines. The inner edge portion 22a of the insulation film 22 is positioned outside the drain region 14. The outer edge portion 22b, in a plan view, is positioned inside the inner edge of the body region 16. In this embodiment, the outer edge portion 22b defines the inner edge 12b of the second potential region 12. In other words, in this embodiment, in a plan view, the region from the outer edge portion 22b of the insulation film 22 to the outer edge of the body region 16 constitutes the second potential region 12. Portions of the body region 16, source region 17, contact region 19, and drift region 13 are exposed from the insulation film 22.

In the insulation film 22, a first region 22c, where an operational region OR of the field resistive film 25, which will be described later, is provided (see FIG. 4), and a second region 22d, where the terminal region TR of the field resistive film 25 is provided (see FIGS. 5 and 6), are defined. Although not illustrated, in this embodiment, the insulation film 22 defines a pair of first regions 22c and a pair of second regions 22d.

The insulation film 23 covers the region outside the transistor region 9. The thickness of the insulation film 23 may be equal to the thickness of the insulation film 22, and the material of the insulation film 23 may be the same as the material of the insulation film 22. The insulation film 23 covers the outer peripheral portion of the body region 16.

As shown in FIGS. 2 and 4 to 6, the semiconductor device 1 includes a field resistive film 25 positioned on the insulation film 22 within the transistor region 9. The field resistive film 25 serves to suppress disturbances in the electric field within the semiconductor region 6 and similar regions, reduce local electric field concentration, and monitor the high-voltage drain-gate voltage Vdg. The field resistive film 25 is a high-resistance film connected to the first potential region 11 and the second potential region 12. The term “field resistive film” may also be referred to as a field electrode or field plate, or the like.

The field resistive film 25 is located above the drift region 13 in the Z direction. In the present embodiment, the field resistive film 25 does not overlap with the channel region 18 in the Z direction. The field resistive film 25 includes, for example, polysilicon. The field resistive film 25 is electrically connected to at least the drain region 14.

In this embodiment, the field resistive film 25 forms a potential gradient that gradually changes from the first potential region 11 to the second potential region 12. By providing such a field resistive film 25, the deviation in the electric field distribution within the drift region 13 is suppressed. The thickness of the field resistive film 25 is, for example, between 50 nm and 100 nm.

As shown in FIG. 2, the field resistive film 25 includes an operational region OR located between the drain region 14 and the source region 17, as well as a terminal region TR located outside the operational region OR in a plan view.

In this embodiment, the operational region OR of the field resistor film 25 is positioned between a pair of terminal regions TR in the Y direction. Each terminal region TR is located outside the operational region OR in the Y direction. In other words, each terminal region TR is positioned outside the operational region OR in a direction that crosses or is orthogonal to the above-mentioned current path. Alternatively, it can be said that one of the terminal regions TR is located, in a plan view, between the drain region 14 and the curved region 12C of the second potential region 12 (or the third region 16C of the body region 16), while the other terminal region TR is located, in a plan view, between the drain region 14 and the curved region 12D of the second potential region 12 (or the fourth region 16D of the body region 16).

The operational region OR is an area within the field resistive film 25 that includes a portion that overlaps with the current path. In a plan view, one end of the operational region OR in the Y direction is positioned between one end 17a of the source region 17 and the end 14a of the drain region 14, but this configuration is not limiting. For example, in a plan view, one end of the operational region OR in the Y direction may be aligned with one end 17a of the source region 17 in the Y direction, or with the end 14a of the drain region 14 in the Y direction, or with one end of the linear section of the drain region 14 in the Y direction. In a plan view, the other end of the operational region OR in the Y direction is positioned between the other end 17b of the source region 17 and the end 14b of the drain region 14, but this configuration is not limiting. For example, in a plan view, the other end of the operational region OR in the Y direction may be aligned with the other end 17b of the source region 17, with the end 14b of the drain region 14, or with the other end of the linear portion of the drain region 14 in the Y direction.

The one end of the operational region OR corresponds to the boundary between the operational region OR and one terminal region TR, and overlaps with the boundary portion between each first region 22c of the insulation film 22 and one second region 22d in the Y direction. The other end of the operational region OR corresponds to the boundary between the operational region OR and the other terminal region TR, and overlaps the boundary portion between each first region 22c of the insulation film 22 and the other second region 22d in the Y direction. Therefore, each of these ends of the operational region OR can be considered as the aforementioned boundary portion.

The operational region OR includes a plurality of first line sections 25a. Each of the plurality of first line sections 25a extends linearly along the Y direction and is spaced apart from each other in the X direction. Each first line section 25a overlaps with the linear portion of the drift region 13 through a corresponding first region 22c of the insulation film 22 in the Z direction. The ends of the first line sections 25a in the Y direction may overlap with the arc section of the drift region 13. In such cases, these ends may extend in an arc shape.

The entirety or the majority of each terminal region TR corresponds to a region in the field resistive film 25 that includes a portion not overlapping with the aforementioned current path. Each terminal region TR includes a plurality of second line portions 25b. Each of these second line portions 25b extends in an arc shape in the X direction and is spaced apart from each other in the Y direction. Each second line portion 25b overlaps with the arc section of the drift region 13 through the second region 22d of the corresponding insulation film 22 (see FIGS. 5 and 6) in the Z direction. The end of the second line portion 25b in the X direction may overlap with the linear portion of the drift region 13. In this case, the end may extend linearly. Each of the plurality of second line portions 25b is connected to the corresponding first line section 25a. As a result, the field resistive film 25 is laid out in a line pattern on the insulation film 22.

For example, the field resistive film 25 may encircle the first potential region 11, which includes the drain region 14, a plurality of times in a concentric pattern in a plan view. The field resistive film 25 may exhibit a spiral shape that surrounds the first potential region 11 in a plan view.

The field resistive film 25 includes a first end 26 positioned near the drain region 14, a second end 27 positioned near the second potential region 12, and a spiral portion 28 extending between the first end 26 and the second end 27. The arrangement of the first end 26 and the second end 27 is arbitrary.

The first end 26 is a connection part that is electrically connected to the drain region 14 and is positioned at the innermost part (innermost peripheral part) of the field resistive film 25. The first end 26, in a plan view, for example, corresponds to the first line part 25a that is located most inward among the plurality of first line parts 25a. The potential applied to the first end 26 is the first potential or a potential close to the first potential. The first end 26 may overlap with the well region 15 in the Z direction.

The second end 27 is the part positioned furthest to the outside (outermost peripheral portion) of the field resistive film 25. The second end 27 corresponds, for example, to the first line section 25a that is positioned furthest to the outside among a plurality of first line portions 25a in a plan view. The potential applied to the second end 27 is the second potential or a potential close to the second potential. The second end 27 may overlap with the drift region 13 in the Z direction. The spiral portion 28 is the connecting portion that links the first end 26 and the second end 27, and in a plan view, it is wound in an elongated spiral shape from the first end 26 to the second end 27 to surround the drain region 14. The spiral portion 28 overlaps with the drift region 13 in the Z direction. Part of the spiral portion 28 may overlap with the well region 15.

The field resistive film 25 forms a potential gradient in the spiral direction from the first end 26 toward the second end 27. Additionally, the field resistive film 25 forms a potential gradient that decreases gradually in accordance with the winding pitch of the spiral portion 28 from the first potential region 11 to the second potential region 12, with respect to the direction orthogonal to the spiral direction. The field resistive film 25 mitigates the electric field intensity within the drift region 13 and suppresses unevenness in the electric field distribution in the drift region 13.

The field resistive film 25 may have a line width ranging between 0.5 μm and 5 μm. The line width is defined by the width in the direction perpendicular to the extending direction (i.e., the spiral direction) of the field resistive film 25. The field resistive film 25 may possess a resistance value ranging between 10 MΩ and 100 MΩ. The line width of each of the first line section 25a and the second line portion 25b may be substantially constant. In cases where the width of the drift region 13 gradually increases toward the center of the arc, the line width of the second line section 25b may also gradually increase toward the center of the arc.

The pitch of the field resistive film 25 may be between 1 μm and 10 μm. The pitch of the field resistive film 25 is defined by the distance between adjacent line portions (i.e., the winding pitch of the spiral portion 28). The number of windings of the field resistive film 25 ranges, for example, between 5 and 100. This number of windings may also be 75 or less, or 50 or less.

The semiconductor device 1 includes an inner field resistive film 29, which is located on an insulation film 22 and connected to the field resistive film 25. The inner field resistive film 29 is positioned closer to the drain region 14 than the field resistive film 25 in a plan view. In this embodiment, the inner field resistive film 29 is located within the region surrounded by the field resistive film 25 in a plan view. The potential of the inner field resistive film 29 is fixed to a first potential. The inner field resistive film 29 may also be a part of the field resistive film 25. In this case, the inner field resistive film 29 functions as the innermost peripheral part of the field resistive film 25. The inner field resistive film 29 includes the same material as the field resistive film 25, such as conductive polysilicon to be described later.

The inner field resistive film 29 is positioned at a location spaced apart from the drain region 14 in a plan view. In this embodiment, the inner field resistive film 29 exhibits an elongated annular elliptical shape surrounding the drain region 14. The inner field resistive film 29 may overlap with the well region 15 in the Z direction. The inner field resistive film 29 includes an inner edge portion 29a and an outer edge portion 29b. The inner edge portion 29a is, for example, provided at a position that maintains a substantially constant distance from the drain region 14 in a plan view. The outer edge portion 29b is, for example, positioned at a location that maintains a substantially constant distance from the spiral portion 28 of the field resistive film 25. The distance between the inner field resistive film 29 and the spiral portion 28 is, for example, equal to the pitch of the field resistive film 25.

In the present embodiment, the width of the inner field resistive film 29 varies unevenly along the circumferential direction. The inner field resistive film 29 has protrusion 30 at its outer edge portion 29b. The protrusion 30 extends toward the field resistive film 25 such that they make contact with the first end 26 of the field resistive film 25. From the viewpoint of suppressing electric field distortion caused by the first end 26 of the field resistive film 25, the protrusion 30 maintains a substantially constant distance between the inner field resistive film 29 and the field resistive film 25. Although the protrusion 30 is connected to the first end 26, this configuration is not limiting. In other words, as long as the inner field resistive film 29 is fixed at the same potential as the first end 26, a direct connection to the first end 26 is not necessary. Consequently, in the spiral direction mentioned above, the protrusion 30 may also be positioned opposite the tip of the first end 26. Furthermore, the inclusion of the inner field resistive film 29 is optional. Therefore, the inner field resistive film 29 may be omitted as needed.

The width of the inner field resistive film 29 is, for example, between 1 μm and 15 μm. The inner field resistive film 29 may be formed wider than the field resistive film 25. In this case, the width of the inner field resistive film 29 is, for example, 1.5 to 5 times the width of the field resistive film 25. Note that the inner field resistive film 29 may have a width equal to or smaller than that of the field resistive film 25.

A semiconductor device 1 includes a gate insulation film 31 that is in contact with the semiconductor region 6 and positioned on the channel region 18. A portion of the gate insulation film 31 overlaps with the insulation film 22. The thickness of the gate insulation film 31 is less than the thickness of the insulation film 22 and is, for example, between 10 nm and 200 nm. The gate insulation film 31 may have a single-layer structure or a laminated structure and may include, for instance, a silicon oxide film. In this embodiment, in a plan view, the gate insulation film 31 presents an elongated annular elliptical shape that surrounds the insulation film 22. The gate insulation film 31 covers a portion of the drift region 13 and a portion of the body region 16.

A semiconductor device 1 includes a gate electrode 32 positioned on a gate insulation film 31. The gate electrode 32 can have materials such as a metal film, an alloy film, or conductive polysilicon. When the gate electrode 32 includes conductive polysilicon, this conductive polysilicon contains at least one of an n-type region and a p-type region. The gate electrode 32 overlaps with not only the channel region 18 but also the drift region 13 in the Z direction. In a plan view, the gate electrode 32 exhibits an elongated annular elliptical shape extending along the channel region 18, but this shape is not limiting. The gate electrode 32 includes a lead-out portion 33 that extends from over the gate insulation film 31 onto the insulation film 22. The lead-out portion 33, in a plan view, exhibits an elongated annular elliptical shape surrounding the field resistive film 25 mentioned later and is positioned over the drift region 13. The entirety of the gate electrode 32, in a plan view, is located outside of the field resistive film 25.

The gate electrode 32 includes an inner edge portion 32a and an outer edge portion 32b. The inner edge portion 32a is formed by the lead-out portion 33. The outer edge portion 32b is positioned in a region overlapping with the body region 16 in a plan view. In this embodiment, the width of the gate electrode 32 is non-uniform along its circumferential direction, but this configuration is not limiting. Specifically, as shown in FIG. 2, the gate electrode 32 includes a gate protrusion 34 that extends toward the drain region 14 at the outer edge portion 32b (lead-out portion 33). The gate protrusion 34 is a section provided in accordance with the shape of the field resistive film 25, which will be described later. By providing the gate protrusion 34, the distance between the gate electrode 32 and the field resistive film 25 is maintained approximately constant in a plan view.

The semiconductor device 1, as shown in FIGS. 4 to 6, includes an insulation layer 40 covering a plurality of device regions 8 on the first main surface 3. The insulation layer 40 has a stacked structure including a plurality of interlayer insulation films 41, which are laminated together. The number of laminations of the interlayer insulation films 41 is arbitrary and is not limited to a specific number. The insulation layer 40 may include three or more interlayer insulation films 41. In FIGS. 4 to 6, the first interlayer insulation film 41A and the second interlayer insulation film 41B among the plurality of interlayer insulation films 41 are shown.

The first interlayer insulation film 41A and the second interlayer insulation film 41B are sequentially stacked in the Z direction. The first interlayer insulation film 41A at least covers the first main surface 3, the insulation film 22, the gate insulation film 31, and the gate electrode 32. The second interlayer insulation film 41B covers the first interlayer insulation film 41A. The thicknesses of the first interlayer insulation film 41A and the second interlayer insulation film 41B are each determined, for example, based on the functionalities required for the field resistive film 25 and the thickness of the insulation film 22. Each of the first interlayer insulation film 41A and the second interlayer insulation film 41B includes at least one of a silicon oxide film and a silicon nitride film. Accordingly, each of the first interlayer insulation film 41A and the second interlayer insulation film 41B may have a single-layer structure or a laminated structure.

Within the insulation layer 40, a plurality of wiring films 42 are provided. In this embodiment, a plurality of interlayer insulation films 41 and a plurality of wiring films 42 are alternately stacked, thereby forming a multi-layer wiring structure above the semiconductor region 6. The number of wiring films 42 stacked is arbitrary and not limited to a specific number. In FIGS. 4 to 6, the first wiring film 42A located on the first interlayer insulation film 41A and the second wiring film 42B located on the second interlayer insulation film 41B are shown. Each wiring film 42 includes at least one of an Al film, a Cu film, an AlSiCu alloy film, an AlSi alloy film, and an AlCu alloy film. Therefore, each of the first wiring film 42A and the second wiring film 42B may have either a single-layer structure or a laminated structure.

Within the insulation layer 40, a plurality of first vias 43 and a plurality of second vias 49 are provided. Each of the plurality of first vias 43 is a conductive portion that electrically connects conductive parts such as the first potential region 11, a second potential region 12, and a field resistive film 25, which are located beneath the first interlayer insulation film 41A, to the first wiring film 42A, and penetrates the first interlayer insulation film 41A. Each of the plurality of second vias 49 is a conductive portion that electrically connects conductive parts such as the first wiring film 42A, which is located beneath the second interlayer insulation film 41B, to the second wiring film 42B, and penetrates the second interlayer insulation film 41B. Each of the plurality of first vias 43 and second vias 49 is, for example, a tungsten plug.

The first wiring film 42A includes, for example, a first drain wiring 44, a first source wiring 45, a first gate wiring 46, a field wiring 47, and a field wiring 48.

The first drain wiring 44 is electrically connected to the drain region 14 via one or more first vias 43. The first source wiring 45 is electrically connected to the source region 17 via one or more first vias 43. The first source wiring 45 may be electrically connected to the source region 17 via one or more first vias 43 in the terminal region TR, for example. The first gate wiring 46 is electrically connected to the gate electrode 32 through one or more first vias 43.

The field wiring 47 is electrically connected to the first end 26 of the field resistor film 25 via one or more first vias 43. The field wiring 47 is, for example, electrically connected to the inner field resistor film 29 via one or more first vias 43. The field wiring 47 may also form part of the first drain wiring 44. The field wiring 48 is electrically connected to the second end 27 of the field resistor film 25 via one or more first vias 43. The field wiring 48 may also form part of the first source wiring 45.

A plurality of second wiring layers 42B include, for example, a second drain wiring 50, a second source wiring 51, and a second gate wiring (not shown).

The second drain wiring 50 is electrically connected to the first drain wiring 44 and the field wiring 47 via the plurality of second vias 49. The second drain wiring 50 overlaps with both the drain region 14 and the field wiring 47. The second drain wiring 50 may overlap with the entire area of the drain region 14 and the entire area of the field wiring 47. Furthermore, the second drain wiring 50 may also overlap with the inner field resistive film 29.

The second source wiring 51 is electrically connected to the first source wiring 45 and the field wiring 48 via the plurality of second vias 49. The second source wiring 51 extends in an annular shape along the body region 16 in a plan view. The second source wiring 51 may overlap with the gate electrode 32 and the field wiring 48. It may overlap with the entire areas of the body region 16, the gate electrode 32, and the field wiring 48. The wiring configuration is not limited to the exemplified configuration. For example, the source region 17 may be wired such that it is fixed at a different potential from the contact region 19.

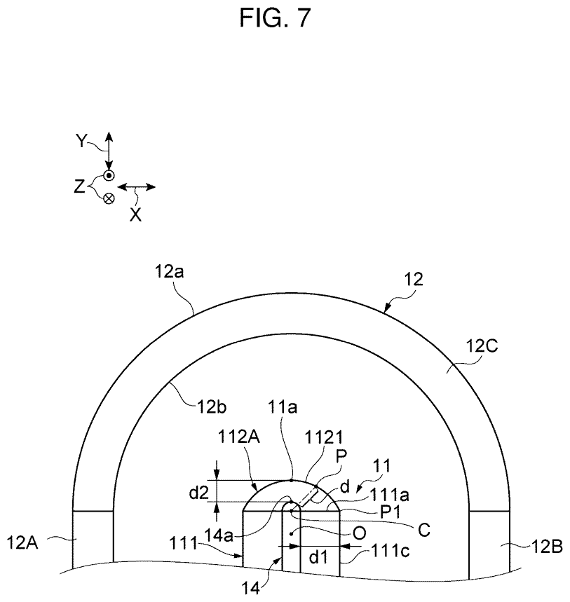

Next, FIG. 7, along with FIGS. 4 to 6, will be used to further describe the first potential region 11. Specifically, the conditions that the end region 112A and end region 112B of the first potential region 11 must satisfy will be described. Since the conditions for the end region 112A and the end region 112B are the same, the end region 112A will be described as an example.

FIG. 7 is a diagram for explaining the end region. In FIG. 7, the vicinity of the end region 112A is shown in an enlarged view. For illustrative purposes, the linear regions 12A and 12B, as well as the curved region 12C of the second potential region 12, are also shown.

Unless otherwise specified, the first potential region 11 is symmetrical with respect to the center line in the X direction of the linear region 111. The aforementioned center line passes through the center of the linear region 111 in the X direction and extends in the Y direction.

As previously described, the first potential region 11 includes the drain region 14. In a plan view, the drain region 14 is positioned at the center of the first potential region 11 in the X direction. A distance d1 between the outer edge (second outer edge) 111c of the linear region 111 of the first potential region 11 and the linear region 141 of the drain region 14 is constant in the Y direction.

The first potential region 11 includes an end region 112A that is continuously connected to the end 111a of the linear region 111. The outer edge 1121 of the end region 112A exhibits a curved shape. The end 11a of the first potential region 11 is located on the outer edge 1121.

As shown in FIG. 7, the distance between the drain region 14 and the outer edge 1121 is referred to as distance d. The distance d may be defined as the distance between the drain region 14 and the outer edge 1121 along a line (indicated by a dash-dot line in FIG. 7) connecting the midpoint C in the X direction of the end 111a of the linear region 111 and an arbitrary point P on the outer edge 1121.

When point P is at the intersection point P1 between the outer edge 1121 and the outer edge (side) 111c, the distance d is defined as distance d1. The distance between end 11a and end 14a along the Y direction is referred to as distance d2. In this embodiment, since the ends 14a and 11a are located on the aforementioned centerline, the distance d2 corresponds to the distance d when point P is at the intersection of the centerline and outer edge 1121. The distance d2 may be zero.

The first potential region 11 is an area that satisfies the condition “in the Y direction, the distance d2 is shorter than the distance d1” (hereinafter referred to as “Condition A”).

The shape of the outer edge 1121 may be an arc. In this case, the radius of curvature of the outer edge 1121 may be the same as the radius of curvature of the inner edge 12b of the curved region 12C. In such a configuration, by forming the first potential region 11 (specifically, the well region 15) so that the center of curvature O of the outer edge 1121 is located within the linear region 111, it is possible to form the first potential region 11 that satisfies the Condition A.

The distance d between the drain region 14 and the outer edge 1121 may decrease in size from the intersection point P1 of the outer edge 1121 and the outer edge 111c towards the end 11a, as illustrated in FIG. 7.

As previously mentioned, the Condition A that the first potential region 11 satisfies has been described using the end region 112A as an example. The same condition is also satisfied by the end region 112B. Specifically, in the description regarding the end region 112A, the terms “end region 112A,” “end 14a,” and “end 111a” may be replaced with “end region 112B,” “end 14b,” and “end 111b,” respectively.

In the semiconductor device 1, the transistor region 9 is designed to withstand voltages by including the insulation film 22 and the field-resistant film 25.

In the semiconductor device 1, both end regions in the Y direction of the first potential region 11 (end regions 112A, 112B) satisfy the Condition A. This configuration improves the breakdown voltage characteristics in the transistor region 9. This point will be described in detail.

In the Y direction ends of the first potential region 11 and the drain region 14, the ends are rounded to alleviate electric field concentration. When the ends are rounded in this manner, typically, the planar view shape of the Y direction end of each of the first potential region 11 and the drain region 14 is an arc. The ends of the first potential region 11 and the drain region 14 are formed such that the distance d shown in FIG. 7 remains constant. A case in which the distance d is constant in this manner is referred to as a reference example. The dash-dot line in FIGS. 5 and 6 indicates the well region on the drain side that defines the first potential region in the reference example.

In contrast, in the semiconductor device 1, the first potential region 11 satisfies the Condition A. In this case, as shown in FIGS. 5 and 6, in the terminal region TR depicted in FIG. 2, the outer edge of the well region 15, which defines the first potential region 11, is formed closer to the drain region 14 compared to the reference example (indicated by the dash-dot line in FIGS. 5 and 6). As a result, the distance between the second potential region 12 and the first potential region 11 in the terminal region TR becomes longer. In this case, the depletion layer tends to expand more easily in the terminal region TR. Consequently, the breakdown voltage of the transistor region 9 is improved.

The external shape of the first potential region 11 in a plan view is defined by the well region 15. Therefore, by adjusting the formation region of the well region 15, the breakdown voltage can be improved. In this case, aside from the point of adjusting the external shape of the well region 15, the layer configuration of the transistor region 9 (which includes a plurality of layers and a laminated state of those layers) is the same as the configuration of the above-mentioned reference example. Although the layer configuration of the transistor region 9 affects the on-resistance, no changes are made to the layer configuration itself in the transistor region 9, so the on-resistance characteristics are substantially maintained. That is, in the semiconductor device 1, it is possible to enhance the breakdown voltage characteristics while maintaining the on-resistance characteristics.

The distance d between the drain region 14 and the outer edge 1121 may decrease from the intersection point P1 of the outer edge 1121 and the outer edge 111c, along the outer edge 1121 toward the end 11a. In this case, the outer edge 1121 at the end in the Y direction of the first potential region 11 can form a smooth curve, making electric field concentration less likely to occur. Consequently, the breakdown voltage characteristics can be more easily improved.

The shape of the end of the first potential region 11 in the Y direction is not restricted, provided that the Condition A is satisfied. For instance, the first potential region may have the end shapes as described in the following Modification Examples 1 and 2. Since the shapes of both end regions of the first potential region in the Y direction are similar, the Modification Examples 1 and 2 will be described with reference to the end region 112A, as in the case shown in FIG. 7.

### Modification Example 1

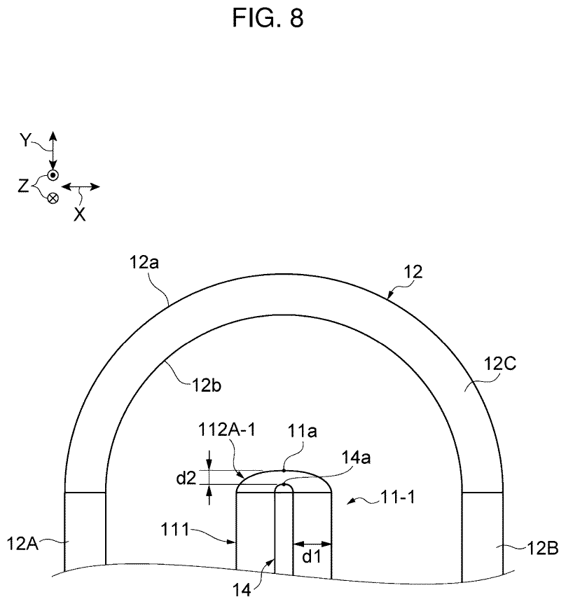

FIG. 8 is a schematic diagram showing a first potential region according to Modification Example 1. FIG. 8 corresponds to the drawing in which the first potential region 11 in FIG. 7 is replaced with the first potential region 11-1 according to Modification Example 1.

The first potential region 11-1 includes a linear region 111 and an end region 112A-1. Since the linear region 111 and the drain region 14 included within the linear region 111 are the same as in the case of the first potential region 11, a detailed description will be omitted.

The end region 112A-1 differs from the end region 112A in that it is formed more flatly. Specifically, in the end region 112A-1, the vicinity of the end 11a is compressed closer to the drain region 14 compared to the case of the end region 112A.

The end region 112A-1 also satisfies the Condition A. Therefore, a semiconductor device employing the first potential region 11-1 instead of the first potential region 11 exhibits similar effects to those of the semiconductor device 1.

### Modification Example 2

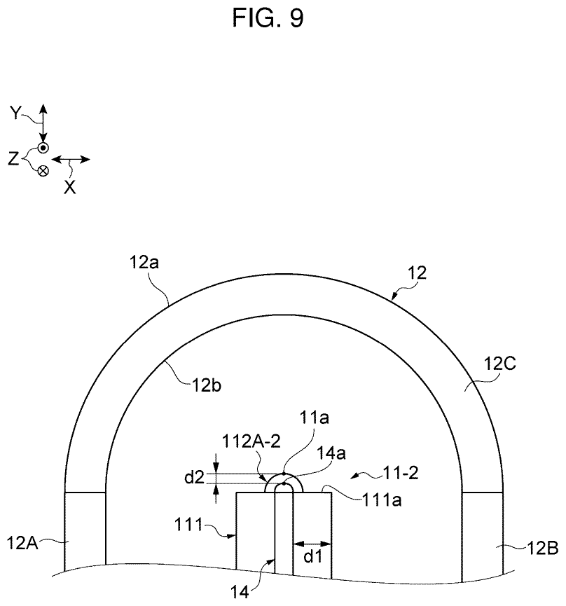

FIG. 9 is a schematic diagram illustrating the first potential region according to Modification Example 2. FIG. 9 corresponds to a drawing in which the first potential region 11 in FIG. 7 is replaced with the first potential region 11-2 according to the Modification Example 2.

The first potential region 11-2 includes a linear region 111 and an end region 112A-2. The linear region 111 and the drain region 14 included within the linear region 111 are the same as those in the case of the first potential region 11, so the description is omitted.

End region 112A-2 is an area where the width in the X direction is shorter than the width of the linear region 111 (corresponding to twice the distance d1). For example, end region 112A-2 takes the form of a semicircle centered on midpoint C, with a radius shorter than distance d1.

The end region 112A-2 also satisfies the Condition A. Therefore, a semiconductor device employing the first potential region 11-1 instead of the first potential region 11 also exhibits the same effects as the semiconductor device 1.

While the embodiments and modification examples pertaining to one aspect of the present disclosure have been described in detail above, these are merely illustrative examples provided to clarify the technical content of the present disclosure. Therefore, the present disclosure should not be construed as being limited to these examples. The scope of the present disclosure is defined only by the appended claims.

For example, in a plan view, the inner edge of the second potential region may be regarded as the inner edge of the source-side body region (e.g., the body region 16 shown in FIGS. 4 to 6). As long as the Condition A is satisfied, the first potential region is not necessarily limited to a configuration symmetrical with respect to the above-mentioned centerline. While the first conductivity type has been described as n-type and the second conductivity type as p-type, the first conductivity type may alternatively be p-type and the second conductivity type may be n-type.

The following are illustrative features extracted from the present specification and the accompanying drawings.

### [A1] (Embodiment, FIGS. 2 to 7)

A semiconductor including:
a semiconductor substrate (7);
a semiconductor layer (6, 10) located on the semiconductor substrate and including, in a plan view:
a first potential region (11) including a drain region (14) extending in a first direction (Y) and to which a first potential is applied;
a second potential region (12) including a source region (17) that surrounds the first potential region and to which a second potential is applied; and
a drift region (13) disposed between the drain region and the second potential region;
a field insulation film (22) covering the drift region; and
a field resistive film (25) provided on the field insulation film and electrically connected to the first potential region and the second potential region, wherein:
the first potential region includes:
a first linear region (111) that extends in the first direction in a plan view and includes at least a part of the drain region; and
an end region (112A, 112B) that is continuously connected to a first end (111a) of the first linear region in the first direction in a plan view and has a curved first outer edge (1121), wherein:
a second end (11a, 11b) of the first potential region in the first direction is located on the first outer edge; and
a distance (d2) in the first direction between a third end (14a,14b) of the drain region and the second end is shorter than a distance (d1) in a second direction (x) intersecting the first direction between the drain region and a second outer edge (111c) of the first linear region.

### [A2] (Embodiment, FIG. 7)

The semiconductor device according to [A1], wherein the distance (d) between the drain region and the first outer edge decreases from the intersection point (P1) of the first end and the first outer edge towards the second end.

### [A3] (Embodiment, FIG. 3)

The semiconductor device according to [A1] or [A2], wherein the second potential region includes:
a pair of second linear regions (12A, 12B) including the source region and extending in the first direction in a plan view;
a first curved region (12C) connecting one end (121a) of each of the pair of second linear regions in a plan view; and
a second curved region (12D) connecting the other end (121b) of each of the pair of second linear regions in a plan view; wherein the radius of curvature of the first outer edge is equal to the radii of curvature of the first curved region and the second curved region.

### [A4] (Embodiment, FIG. 3)

The semiconductor device according to any one of [A1] to [A3], wherein:
the shape of the first potential region is an elongated elliptical shape in a plan view;
the shape of the second potential region is an elongated annular elliptical shape in a plan view;
the first direction corresponds to the major axis direction of both the first potential region and the second potential region; and
the second direction corresponds to the minor axis direction of both the first potential region and the second potential region.

### [A5] (Embodiment, FIG. 7)

The semiconductor device according to any one of [A1] to [A4], wherein the shape of the first outer edge is an arc, and the center of curvature (O) of the arc is located within the first linear region in a plan view.

### [A6] (Embodiment, FIGS. 4 to 6)

The semiconductor device according to any one of [A1] to [A5], wherein the first potential region is adjacent to the drain region and includes a first semiconductor region (15) that surrounds the drain region in a plan view, and
the second potential region is adjacent to the source region and includes a second semiconductor region (16) that extends along the second potential region in a plan view.

### [A7] (Embodiment, FIGS. 4 to 6)

The semiconductor device according to any one of [A1] to [A6], further including: in a plan view,
a gate insulation film (31) provided between the source region and the field insulation film; and
a gate electrode (32) provided on the gate insulation film.

### A8

The semiconductor device according to any one of [A1] to [A7], wherein the second potential is lower than the first potential.

1. A semiconductor device, comprising:
a semiconductor substrate;
a semiconductor layer formed on the semiconductor substrate, the semiconductor layer including, in a plan view of the semiconductor device:
a first potential region to which a first potential is applied, the first potential region including a drain region extending in a first direction;
a second potential region to which a second potential is applied, the second potential region including a source region that surrounds the first potential region; and
a drift region disposed between the drain region and the second potential region;
a field insulation film covering the drift region; and
a field resistive film provided on the field insulation film and electrically connected to the first potential region and the second potential region, wherein:
the first potential region includes:
a linear region that extends in the first direction, at least a part of the drain region overlapping the linear region in the plan view; and
an end region that is continuously connected to an end of the linear region in the first direction in the plan view, and has a curved outer edge, wherein
the first potential region has an end that in the first direction is located on the curved outer edge of the end region; and
a distance in the first direction between an end of the drain region and the end of the first potential region is shorter than a distance in a second direction intersecting the first direction between the drain region and an outer edge of the linear region.

2. The semiconductor device according to claim 1, wherein:
the end of the linear region and the curved outer edge of the end region intersect at an intersection point, and
a distance, in a radial direction of the curved outer edge of the end region, between the drain region and the curved outer edge decreases from the intersection point towards the end of the first potential region.

3. The semiconductor device according to claim 2, wherein
the linear region of the first potential region is a first linear region; and
the second potential region comprises:
a pair of second linear regions, each extending in the first direction in the plan view and having a first end and a second end in the first direction, the source region overlapping the pair of second linear regions in the plan view;
a first curved region, which connects the first ends of the pair of second linear regions; and
a second curved region, which connects the second ends of the pair of second linear regions, wherein
the curved outer edge of the end region of the first potential region, and the first curved region and the second curved region of the second potential region have a same radius of curvature.

4. The semiconductor device according to claim 2, wherein in the plan view:
the first potential region is of an elongated elliptical bar shape;
the second potential region is of an elongated elliptical annular shape;
a major axis direction of the first potential region and that of the second potential region are both in the first direction; and
a minor axis direction of the first potential region and that of the second potential region are both in the second direction.

5. The semiconductor device according to claim 2, wherein, in the plan view,
the curved outer edge of the end region of the first potential region is of an arc shape, and
a center of curvature of the arc is located within the linear region of the first potential region.

6. The semiconductor device according to claim 2, wherein:
the first potential region is adjacent to the drain region and includes a first region that surrounds the drain region in the plan view; and
the second potential region is adjacent to the source region and includes a second region that extends along the second potential region in the plan view.

7. The semiconductor device according to claim 2, further comprising:
a gate insulation film, which is provided, in the plan view, between the source region and the field insulation film; and
a gate electrode provided on the gate insulation film.

8. The semiconductor device according to claim 2, wherein the second potential is a potential lower than the first potential.

9. The semiconductor device according to claim 1, wherein
the linear region of the first potential region is a first linear region; and
the second potential region comprises:
a pair of second linear regions, each extending in the first direction in the plan view and having a first end and a second end in the first direction, the source region overlapping the pair of second linear regions in the plan view;
a first curved region, which connects the first ends of the pair of second linear regions; and
a second curved region, which connects the second ends of the pair of second linear regions, wherein
the curved outer edge of the end region of the first potential region, and the first curved region and the second curved region of the second potential region have a same radius of curvature.

10. The semiconductor device according to claim 1, wherein in the plan view:
the first potential region is of an elongated elliptical bar shape;
the second potential region is of an elongated elliptical annular shape;
a major axis direction of the first potential region and that of the second potential region are both in the first direction; and
a minor axis direction of the first potential region and that of the second potential region are both in the second direction.

11. The semiconductor device according to claim 1, wherein, in the plan view,
the curved outer edge of the end region of the first potential region is of an arc shape, and
a center of curvature of the arc is located within the linear region of the first potential region.

12. The semiconductor device according to claim 1, wherein:
the first potential region is adjacent to the drain region and includes a first region that surrounds the drain region in the plan view; and
the second potential region is adjacent to the source region and includes a second region that extends along the second potential region in the plan view.

13. The semiconductor device according to claim 1, further comprising:
a gate insulation film, which is provided, in the plan view, between the source region and the field insulation film; and
a gate electrode provided on the gate insulation film.

14. The semiconductor device according to claim 1, wherein the second potential is a potential lower than the first potential.
